(19) United States
(12) Patent Application Publication
(10) Pub. No.: US 2004/0023155 A1
(43) Pub. Date: Feb. 5, 2004

(54) Composition for a thermal lithographic printing plate and lithographic printing plate comprising the composition

(76) Inventors: Eiji Hayakawa, Utsunomiya-shi (JP); Masamichi Kamiya, Ota-shi (JP); Motohiro Tsushima, Tatebayashi-shi (JP); Yasuhiro Asawa, Gyoda-shi (JP)

Correspondence Address: RATNERPRESTIA, P.O. BOX 1596, WILMINGTON, DE, 19899, US

(21) Appl. No.: 10/209,724

(22) Filed: Aug. 1, 2002

(51) Int. Cl. G03F 7/039; G03C 1/492

(52) U.S. Cl. 430/271.1; 430/270.1; 430/273.1; 430/281.1; 430/283.1; 430/288.1; 430/302; 430/348; 430/434

(57) ABSTRACT

Thermally imageable elements useful in lithographic printing are disclosed. The element has a layer of an imageable composition over a support. The imageable composition contains a supramolecular polymer that includes QHB-modified polymeric molecules having the structure A-L-B. A and B are each different QHB-modified portions selected from QHB-modified phenolic portions, QHB-modified acrylic portions, QHB-modified polyester portions, and QHB-modified polyurethane portions. L is a joining group. The elements are suitable for the preparation of lithographic printing plates.

### FIELD OF THE INVENTION

The invention relates to thermally imageable elements useful in lithographic printing. More particularly, this invention relates to thermally sensitive polymers useful in thermally imageable compositions and to positive working thermally imageable elements comprising the compositions.

### BACKGROUND OF THE INVENTION

In lithographic printing, ink receptive regions, known as image areas, are generated on a hydrophilic surface. When the surface is moistened with water and ink is applied, the hydrophilic regions retain the water and repel the ink, and the ink receptive regions accept the ink and repel the water. The ink is transferred to the surface of a material upon which the image is to be reproduced. Typically, the ink is first transferred to an intermediate blanket, which in turn transfers the ink to the surface of the material upon which the image is to be reproduced.

Imageable elements useful for the preparation of lithographic printing plates typically comprise an imageable layer over the hydrophilic surface of a substrate. The imageable layer comprises one or more radiation-sensitive components, which may be dispersed in a suitable binder. Alternatively, the radiation-sensitive component can also be the binder material.

If after exposure to radiation, the exposed regions of the imageable layer are removed in the developing process, revealing the underlying hydrophilic surface of the substrate, the element is positive working. Conversely, if the developing process removes the unexposed regions, and the exposed regions remain, the element is negative working. In each instance, the regions of the radiation-sensitive layer (i.e., the image areas) that remain are ink-receptive and the regions of the hydrophilic surface revealed by the developing process accept water, typically a fountain solution, and repel ink.

Direct digital imaging of offset printing plate precursors, which obviates the need for exposure through a negative, is becoming increasingly important in the printing industry. Positive-working thermally imageable elements that comprise a thermally imageable layer over the substrate have been disclosed. On thermal imaging, the exposed regions of the imageable layer become soluble in, or permeable by, an alkaline developer. The developer penetrates the imageable layer and removes the imageable layer and, if present, an underlayer, revealing the surface of the underlying substrate in the exposed regions.

The imageable layer of certain of these thermally imageable elements comprises a dissolution inhibitor, which suppresses removal of the imageable layer in the unexposed regions. Because the dissolution inhibitor is sometimes sensitive to “white light” or “room light,” the resulting imageable element cannot be handled in room light. In addition, in use a lithographic printing plate comes in contact with fountain solution and is often subjected to aggressive blanket washes, such as a “UV wash,” to remove ultraviolet curable ink. However, many of these thermally imageable elements have limited resistance to either fountain solution and/or aggressive blanket washes. Thus, a need exists for thermally imageable elements, useful as lithographic printing plate precursors, that do not suffer from these disadvantages.

### SUMMARY OF THE INVENTION

In one aspect, the invention is a QHB-modified polymeric molecule having the structure A-L-B,

in which:

A is a QHB-modified phenolic portion, a QHB-modified acrylic portion, a QHB-modified polyester portion, or a QHB-modified polyurethane portion;

B is a QHB-modified phenolic portion, a QHB-modified acrylic portion, a QHB-modified polyester portion, or a QHB-modified polyurethane portion;

L is a joining group; and

A and B are different.

In another aspect, the invention is a thermally sensitive supramolecular polymer comprising a plurality the QHB-modified polymeric molecules. The supramolecular polymer has an increased rate of solubility in an aqueous developer following thermal exposure.

In another aspect, the invention is a thermally imageable composition comprising the thermally sensitive supramolecular polymer and, typically, a photothermal conversion material. In another aspect, the invention is a thermally imageable element useful as printing plate precursor comprising a layer of the imageable composition over a substrate that comprises a hydrophilic surface.

In another aspect, the invention is a method for producing an image useful as a lithographic printing plate, the method comprising the steps of:

imaging the imageable element, and forming an imaged element comprising exposed and unexposed regions in the imageable layer; and

developing the imaged element and removing the exposed regions.

### DETAILED DESCRIPTION OF THE INVENTION

Unless the context indicates otherwise, in the specification and claims, the terms supramolecular polymer, phenolic polymer, acrylic polymer, joining agent, QHB-modified polymer, photothermal conversion material, and similar terms include mixtures of such materials. Unless otherwise specified, all percentages are percentages by weight. The term “QHB-modified” refers to a molecule or a portion of a molecule that comprises a structural feature, or QHB (quadruple hydrogen bonding) unit, that is capable of forming four or more, typically four, hydrogen bonds with similar or complementary units on other molecules or portions of molecules. The term “hydrocarbylene” refers to a linear, branched or cyclic alkylene, vinylene, arylene, aralkylene or alkarylene of 1 to 22 carbon atoms or substituted derivatives thereof, in which the substituent group or groups are halogen, hydroxyl, carboxyl, hydrocarbyloxyl, ester, ketone, cyano, amino, amido and/or nitro groups. Hydrocarbylene groups in which the carbon chain is interrupted by oxygen, nitrogen or sulfur are also included in the term “hydrocarbylene”.

### Thermally Sensitive Polymers

The thermally sensitive polymer is a supramolecular polymer (“suprapolymer”) comprising polymeric molecules linked via hydrogen bridges. The polymeric molecules are QHB (quadruple hydrogen bonding) modified polymeric molecules, that is molecules that comprises a quadruple hydrogen bonding unit.

### Supramolecular Polymers

A “supramolecular polymer” is one that derives its polymeric properties from a combination of covalent bonds and specific secondary interactions, which includes hydrogen bonding, particularly by two or more hydrogen bonds. Such secondary interactions provide high bond strength and contribute substantially to the properties of the supramolecular polymer. Bifunctional compounds that can associate by a two hydrogen bond unit, for example, bridged bipyridones, are disclosed in J. Org. Chem., 53, 5787-9 (1988). Trifunctional compounds that can associate by a three hydrogen bond unit, for example malimide units associated with 2,6-diaminotriazine units, are disclosed in Macromolecules, 28, 782-83 (1995). Supramolecular polymers comprising polymeric molecules that, in pairs form at least four hydrogen bonds with one another, are disclosed in Sijbesma, U.S. Pat. No. 6,320,018, incorporated herein by reference.

A QHB unit is a unit that can be linked via at least four hydrogen bonds to another QHB unit. In a QHB-modified polymer, at least two QHB units are attached to a polymeric molecule by covalent bonds. Formation of the at least four hydrogen bonds between the QHB units on the QHB-modified polymers produces the supramolecular polymer.

The QHB units that can be used may be self-complementary, that is, all the QHB-modified polymers have identical QHB units. It is, however, also possible for the supramolecular polymer to contain two or more different types of QHB units that form at least four hydrogen bonds between each other. A combination is also possible. Preferably, the hydrogen bonds are oriented parallel to one another.

The QHB units preferably have an essentially flat, rigid structure. In particular, the unit preferably contains one or more flat six-membered rings. Preferably the QHB units have two successive donors, followed by two acceptors. In one preferred embodiment, the QHB units are isocytosine units (isocytosine moieties) and the QHB-modified polymeric molecules comprise at two isocytosine units.

The QHB-modified polymeric molecules that comprise the supramolecular polymer comprise portions derived from two different types of polymers, joined by a joining group. Each portion is derived from either a QHB-modified phenolic polymer, a QHB-modified acrylic polymer, a QHB-modified polyester polymer, or a QHB-modified polyurethane polymer. In one aspect, a portion derived from a QHB-modified acrylic polymer is joined to a portion derived from a QHB-modified phenolic polymer, a QHB-modified polyester polymer, or a QHB-modified polyurethane polymer by a joining group. In another aspect, a portion derived from a QHB-modified acrylic polymer is joined to a portion derived from a QHB-modified phenolic polymer by a joining group. The supramolecular polymer may also comprise polymeric molecules that comprise two portions derived from the same type of QHB-modified polymer and/or QHB-modified polymers that are not joined to other QHB-modified polymers by a joining group.

For developability, the portions derived from the QHB-modified polymers should have at least one base-soluble functional group having a pKₐ of less than 14. Such base-soluble functional groups include, for example, carboxylic, sulfonic, imide, N-acyl sulfonamide and phenolic hydroxyl groups.

### Formation of QHB-modified Polymers

A QHB-modified polymer can be prepared by reaction of, for example, an isocytosine such as a 6-alkyl isocytosine, typically 6-methyl isocytosine, with an isocyanate to produce an isocytosine/isocyanate mono-adduct, i.e. a quadruple hydrogen bonding entity (QHBE). The quadruple hydrogen bonding entity is reacted with the appropriate polymer to produce the QHB-modified polymer. The 6-methyl isocytosine/isocyanate mono-adduct, a QHBE, is represented by the formula:

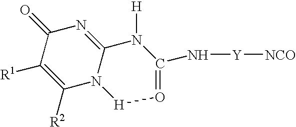

in which R¹ is hydrogen, R² is methyl, and Y is a hydrocarbylene derived from a diisocyanate represented by the formula Y(NCO)₂.

Any diisocyanate may be used to prepare the QHBE. Suitable diisocyanates include, for example, isophorone diisocyanate, methylene-bisphenyl diisocyanate, toluene diisocyanate, hexamethylene diisocyanate, tetramethylxyxylene diisocyanate, dimers thereof, adducts thereof with diols, and mixtures thereof. A preferred diisocyanate is isophorone diisocyanate.

Reaction of one mole of the isocytosine with one mole of the diisocyanate produces the QHBE, which will spontaneously dimerize to form a dimeric mono-adduct joined by four thermally reversible hydrogen bonds. The resulting dimeric QHBE has a free isocyanate group on each end, which can react with the appropriate polymer to produce a QHB-modified polymer.

The QHBE is reacted with the appropriate polymer to form the desired QHB-modified polymer. The QHBE may be reacted with an acrylic polymer, a phenolic polymer, a polyester polymer, or a polyurethane polymer to produce a QHB-modified acrylic polymer, a QHB-modified phenolic polymer, a QHB-modified polyester polymer, or a QHB-modified polyurethane polymer, respectively. When the QHBE is formed from 6-methyl isocytosine, the QHB-modified polymeric molecule produced by reaction of a polymer with the QHBE comprises a 6-methyl isocytosine QHB unit, i.e., the 6-methyl isocytosine moiety.

Unreacted diisocyanate in the QHBE can crosslink the polymer by reaction with two molecules of the polymer. To avoid crosslinking of the unmodified polymer by unreacted diisocyanate, an excess of isocytosine, i.e., about 10-20% molar excess, is preferably used. However, excess isocytosine can further react with the QHBE to give an adduct having two isocytosine units. To maximize the formation of lower order adducts, isocytosine is added slowly to the diisocyanate so that excess diisocyanate is present at the early stages of the QHBE formation reaction.

Carboxyl substituted acrylic polymers may be used as the acrylic polymer. These include, for example, polymers and copolymers of acrylic acid and/or methacrylic acid with, for example, alkyl esters of acrylic acid such as methyl acrylate and ethyl acrylate; alkyl esters of methacrylic acid such as methyl methacrylate and ethyl methacrylate; hydroxyethyl acrylate; hydroxyethyl methacrylate, hydroxypropyl acrylate, hydroxypropyl methacrylate; amides of acrylic acid such as acrylamide and N-methylacrylamide; amides of methacrylic acid such as methacrylamide and N-methylmethacrylamide; acrylonitrile; methacrylonitrile; vinyl chloride; maleic anhydride; itoconic acid; vinylidene chloride; vinyl acetate; vinyl ether; styrene; and N-phenylmaleimide.

Acrylic polymers that provide resistance both to fountain solution and aggressive washes are disclosed in Shimazu, U.S. Pat. No. 6,294,311, incorporated herein by reference. Especially useful are acrylic copolymers that comprise, in polymerized form, a monomer that has a urea bond in its side chain (i.e., a pendent urea group), such are disclosed in Ishizuka, U.S. Pat. No. 5,731,127. These copolymers comprise about 10 to 80 wt %, preferably about 20 to 80 wt %, of one of more monomers represented by the general formula:

CH₂═C(R)—CO₂—X—NH—CO—NH—Y—Z,

in which R is —H or —CH₃; X is a bivalent joining group; Y is a substituted or unsubstituted bivalent aromatic group; and Z is —OH, —COOH, or —SO₂NH₂.

R is -preferably CH₃. Preferably X is a substituted or unsubstituted alkylene group, substituted or unsubstituted phenylene [C₆H₄] group, or substituted or unsubstituted naphthalene [C₁₀H₆] group; such as —(CH₂)ₙ—, in which n is 2 to 8; 1,2-, 1,3-, and 1,4-phenylene; and 1,4-, 2,7-, and 1,8-naphthalene. More preferably X is unsubstituted and even more preferably n is 2 or 3; most preferably X is —(CH₂CH₂)—. Preferably Y is a substituted or unsubstituted phenylene group or substituted or unsubstituted naphthalene group; such as 1,2-,1,3-, and 1,4-phenylene; and 1,4-, 2,7-, and 1,8-naphthalene. More preferably Y is unsubstituted, most preferably unsubstituted 1,4-phenylene. Z is —OH, —COOH, or —SO₂NH₂, preferably —OH. A preferred monomer is:

CH₂═C(CH₃)—CO₂—CH₂CH₂—NH—CO—NH-p-C₆H₄-Z,

in which Z is —OH, —COOH, or —SO₂NH₂, preferably —OH.

In the synthesis of a copolymer, one or more of the urea group containing monomers may be used. The copolymers also comprise 20 to 90 wt % other polymerizable monomers, such as maleimide, acrylic acid, methacrylic acid, acrylic esters, methacrylic esters, acrylonitrile, methacrylonitrile, acrylamides, and methacrylamides. A copolymer that comprises in excess of 60 mol % and not more than 90 mol % of acrylonitrile and/or methacrylonitrile in addition to acrylamide and/or methacrylamide provides superior physical properties. More preferably the alkaline soluble copolymers comprise 30 to 70 wt % urea group containing monomer; 20 to 60 wt % acrylonitrile or methacrylonitrile, preferably acrylonitrile; and 5 to 25 wt % acrylamide or methacrylamide, preferably methacrylamide.

These polymeric materials can be prepared by methods, such as free radical polymerization, well known to those skilled in the art. Synthesis of copolymers that have urea bonds in their side chains is disclosed, for example, in Ishizuka, U.S. Pat. No. 5,731,127.

Phenolic polymers are typically water-insoluble, alkaline developer soluble or removable, film-forming polymeric materials that have a multiplicity of phenolic hydroxyl groups either on the polymer backbone or on pendant groups. Novolac resins, resol resins, acrylic resins that contain pendent phenol groups, and polyvinyl phenol resins are preferred phenolic resins. Other useful phenolic resins include polyvinyl compounds having phenolic hydroxyl groups. Such compounds include, for example, polyhydroxystyrenes and copolymers containing recurring units of a hydroxystyrene, and polymers and copolymers containing recurring units of substituted hydroxystyrenes.

Novolac resins are more preferred. Novolac resins are commercially available and are well known to those skilled in the art. They are typically prepared by the condensation reaction of a phenol, such as phenol, m-cresol, o-cresol, p-cresol, etc, with an aldehyde, such as formaldehyde, paraformaldehyde, acetaldehyde, etc. or ketone, such as acetone, in the presence of an acid catalyst. The weight average molecular weight is typically about 1,000 to 15,000. Typical novolac resins include, for example, phenol-formaldehyde resins, cresol-formaldehyde resins, phenol-cresol-formaldehyde resins, p-t-butylphenol-formaldehyde resins, and pyrogallol-acetone resins.

Useful polyester polymers may be prepared by reaction of dianhydride compounds with hydroxyl-containing polyester precursors composed of dicarboxylic acid units and glycol units. Useful hydroxyl-containing polyester precursors include, for example, oligoester diols which are the reaction product of a dicarboxylic acid such as succinic acid, adipic acid, azelaic acid, sebacic acid, phthalic acid, isophthalic acid, terephthalic acid, tetrahydrophthalic acid, hexahydrophthalic acid, tetrabromophthalic acid, tetrachlorophthalic acid, 1,4-cyclohexanedicarboxylic acid, maleic acid, fumaric acid, itaconic acid and 5-sodiumsulfoisophthalic acid, with a diol such as ethylene glycol, diethylene glycol, triethylene glycol, polyethylene glycol, 1,2- or 1,3-propanediol, polypropylene glycol, 1,2- or 1,4-butanediol, neopentyl glycol, or 1,6-hexanediol. Useful dianhydrides include, for example, pyromellitic dianhydride, 3,3′,4,4′-benzophenone tetracarboxylic dianhydride, 3,3′,4,4′-diphenyl tetracarboxylic dianhydride, or 2,3,6,7-naphthalene tetracarboxylic dianhydride.

Useful polyurethane polymers may be prepared by reaction of carboxyl functional diols with diisocyanates. Useful carboxyl functional diols include, for example, dimethylol propionic acid, dihydroxybenzoic acids and the reaction product of a dianhydride such as pyromellitic dianhydride, 3,3′,4,4′-benzophenone tetracarboxylic dianhydride, 3,3′,4,4′-diphenyl tetracarboxylic dianhydride, or 2,3,6,7-naphthalene tetracarboxylic dianhydride with a diol such as ethylene glycol, diethylene glycol, triethylene glycol, polyethylene glycol, 1,2-or 1,3-propanediol, polypropylene glycol, 1,2- or 1,4-butanediol, neopentyl glycol, or 1,6-hexanediol.

The joining agent may be any molecule that contains two reactive functional groups that can react with the functional groups present in the QHB-modified polymers. Selection of the joining agent will depend on the reactive functionality present in the QHB-modified polymers to be joined. Typically the QHB-modified polymers contain hydroxyl and/or carboxyl groups that react with the joining agent. Useful joining agents include, for example, diepoxides, such as bis phenol A diglycidyl ether, 3,4-epoxycyclohexylmethyl-3′,4′-epoxycyclohexane-carboxylate (ECC), vinylcyclohexane diepoxide, limonene diepoxide, and diglycidyl ethers of various diols, such as 1,6-hexane diol, diethylene glycol, and neopentyl glycol; diarizidines; diisocyanates, such as isophorone diisocyanate, methylene-bis-phenyl diisocyanate, toluene diisocyanate, hexamethylene diisocyanate, and tetramethylxylylene diisocyanate; diacid halides, such as malonyl chloride, succinyl chloride, glutaroyl chloride, adipoyl chloride, phthaloyl chloride, and terephthaloyl chloride; disulfonic acid halides; and dialkyl halides, such as 1,4-dichlorobutane and 1,3-dibromopropane.

When the joining agent is a diacid halide, the joining group will have the general structure:

—CO-T-CO—

in which T is a hydrocarbylene group such as 1,2-, 1,3-, or 1,4-phenylene or —CₙH₂ₙ—, in which n is typically 0 to 8, more typically 2 to 6.

When the joining agent is a diisocyanate, the joining group has the structure:

—C(O)—NH-T-NH—C(O)—

in which T is as described above.

When the joining agent is a diepoxide, the joining group has the structure:

—CH₂—CH(OH)-T-CH(OH)—CH₂—

in which T is as described above.

When the joining agent is a dialkyl halide, the joining group has the structure:

—CH₂-T-CH₂—

in which T is as described above.

Reaction of the QHB-modified polymers with the joining agent produces a QHB-modified polymer having the structure A-L-B. A is a QHB-modified phenolic portion, a QHB-modified acrylic portion, a QHB-modified polyester portion, or a QHB-modified polyurethane portion. B is a QHB-modified phenolic portion, a QHB-modified acrylic portion, a QHB-modified polyester portion, or a QHB-modified polyurethane potion. L is a joining group.

A and B are different. For example, if A is a QHB-modified acrylic portion, then B is a QHB-modified phenolic portion, a QHB-modified polyester, or a QHB-modified polyurethane potion, but not a QHB-modified acrylic portion. Or, for example, if A is a QHB-modified phenolic portion, then B is a QHB-modified acrylic portion, a QHB-modified polyester portion, or a QHB-modified polyurethane potion, but not QHB-modified phenolic portion.

In a preferred embodiment, A is a QHB-modified acrylic portion, and B is a QHB-modified phenolic portion, a QHB-modified polyester portion, or a QHB-modified polyurethane potion. In another preferred embodiment, A is a QHB-modified acrylic portion, and B is a QHB-modified phenolic portion.

Association of the QHB-modified polymers described above forms the thermally sensitive supramolecular polymer. The supramolecular polymer may also comprise QHB-modified polymers that have not been joined to other QHB-modified polymers to form QHB-modified polymers of the A-L-B structure described above. The supramolecular molecule may also comprise QHB-modified polymers in which A and B are the same. That is, the supramolecular polymer may also comprise QHB-modified polymers of the structure A-L-B in which both A and B are either QHB-modified phenolic portions, QHB-modified acrylic portions, QHB-modified polyester portions, or QHB-modified polyurethane portions.

### Imageable Composition

The imageable composition comprises a thermally sensitive supramolecular polymer, as described above, removable by an alkaline developer following heating. The thermally imageable composition may also comprise other ingredients that are conventional components of thermally imageable compositions.

### Photothermal Conversion Material

When the element is to be exposed with infrared radiation, the element comprises a photothermal conversion material. When the element is to be imaged with a thermal printing head, it is not necessary that the element comprise a photothermal conversion material. The photothermal conversion material may be present in the imageable layer, and/or, if present, the underlayer. Photothermal conversion materials absorb radiation and convert it to heat. Photothermal conversion materials may absorb ultraviolet, visible, and/or infrared radiation and convert it to heat.

The photothermal conversion material may be either a dye or pigment, such as a dye or pigment of the squarylium, merocyanine, indolizine, pyrylium, or metal diothiolene class. Examples of absorbing pigments are Projet 900, Projet 860 and Projet 830 (all available from the Zeneca Corporation), and carbon black. Dyes, especially dyes with a high extinction coefficient in the range of 750 nm to 1200 nm, are preferred. Absorbing dyes are disclosed in numerous publications, for example, Nagasaka, EP 0 823 327; Van Damme, EP 0 908 397; DeBoer, U.S. Pat. No. 4,973,572; Jandrue, U.S. Pat. No. 5,244,771; and Chapman, U.S. Pat. No. 5,401,618. Photothermal conversion materials are also disclosed in Hauck, U.S. Pat. No. 6,309,792, especially column 5, line 10, to col. 9, line 44. Examples of useful absorbing dyes include, ADS-830A and ADS-1064 (American Dye Source, Montreal, Canada), EC2117 (FEW, Wolfen, Germany), Cyasorb IR 99 and Cyasorb IR 165 (Glendale Protective Technology), Epolite IV62B and Epolite 111-178 (Epoline), PINA-780 (Allied Signal), SpectralR 830A and SpectralR 840A (Spectra Colors), and IR Dye A and IR Dye B, whose structures are shown below.

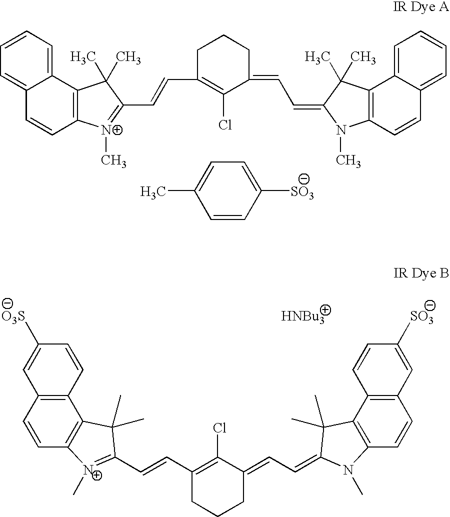

The amount of photothermal conversion material in the element is generally sufficient to provide an optical density of at least 0.05, and preferably, an optical density of from about 0.5 to about 2 at the imaging wavelength. The amount of photothermal conversion material required to produce a particular optical density can be determined from the thickness of the layer and the extinction coefficient of the absorber at the wavelength used for imaging using Beers law.

### Other Ingredients

The imageable layer may also comprise a dye to aid in the visual inspection of the exposed and/or developed element. However, when the photothermal conversion material is in the underlayer, the imageable layer should not absorb the imaging radiation so dyes that absorb the imaging radiation should not be used in the imageable layer. Printout dyes distinguish the exposed regions from the unexposed regions during processing. Contrast dyes distinguish the unimaged regions from the imaged regions in the developed imageable element. Triarylmethane dyes, such as ethyl violet, crystal violet, malachite green, brilliant green, Victoria blue B, Victoria blue R, and Victoria pure blue BO, may act as a contrast dye.

The storage stability of the thermally imageable composition may be improved by addition a storage stabilizer or a mixture of storage stabilizers. Typical storage stabilizers are, for example, copper compounds, such as copper naphthenate, copper stearate and copper octoate; phosphorus compounds, such as triphenylphosphine, tributylphosphine, triethyl phosphite, triphenyl phosphite and tribenzyl phosphite; quaternary ammonium compounds, such as tetramethylammonium chloride and trimethylbenzylammonium chloride, hydroxylamine derivatives, such as N-diethylhydroxylamine; and heterocyclic mercapto compounds such as 2-mercapto-imidazole, 3-mercapto-1,2,4-triazole; 2-mercaptobenzimidazole; 2-mercaptobenzoxazole; 5-mercapto-3-methylthio-1,2,4-thiadiazole; and 2-mercapto-1-methylimidazole. The infrared-sensitive compositions preferably comprise about 0.5 to about 20 wt %, preferably about 2 to about 8 wt %, of the storage stabilizer or mixture of storage stabilizers.

### Imageable Elements

The imageable element comprises a layer of the thermally imageable composition over the hydrophilic surface of a substrate. An underlayer may be present between the substrate and the imageable layer.

### Substrate

The substrate that comprises at least one hydrophilic surface comprises a support, which may be any material conventionally used to prepare imageable elements useful as lithographic printing plates. The support is preferably strong, stable and flexible. It should resist dimensional change under conditions of use so that color records will register in a full-color image. Typically, it can be any self-supporting material, including, for example, polymeric films such as polyethylene terephthalate film, ceramics, metals, or stiff papers, or a lamination of any of these materials. Metal supports include aluminum, zinc, titanium, and alloys thereof.

Typically, polymeric films contain a sub-coating on one or both surfaces to modify the surface characteristics to enhance the hydrophilicity of the surface, to improve adhesion to subsequent layers, to improve planarity of paper substrates, and the like. The nature of this layer or layers depends upon the substrate and the composition of subsequent coated layers. Examples of subbing layer materials are adhesion-promoting materials, such as alkoxysilanes, amino-propyltriethoxysilane, glycidoxypropyltriethoxysilane and epoxy functional polymers, as well as conventional subbing materials used on polyester bases in photographic films.

The surface of an aluminum support may be treated by techniques known in the art, including physical graining, electrochemical graining, chemical graining, and anodizing. The substrate should be of sufficient thickness to sustain the wear from printing and be thin enough to wrap around a printing form, typically from about 100 to about 600 μm. Typically, the substrate comprises an interlayer between the aluminum support and the imageable layer. The interlayer may be formed by treatment of the support with, for example, silicate, dextrine, hexafluorosilicic acid, phosphate/fluoride, polyvinyl phosphonic acid (PVPA) or polyvinyl phosphonic acid copolymers.

The back side of the substrate (i.e., the side opposite the underlayer and imageable layer) may be coated with an antistatic agent and/or a slipping layer or matte layer to improve handling and “feel” of the imageable element.

### Imageable Layer

The imageable layer is over the hydrophilic surface of the support. It comprises a layer of the imageable composition described above. When an underlayer is not present, the coating weight of the imageable layer is typically about 0.5 to 5 g/m². When an underlayer is present, the coating weight of the imageable layer is typically about 0.25 to 5 g/m² and the coating weight of the underlayer is about 0.5 to 5 g/m².

### Underlayer

The element may also comprise an underlayer between the imageable layer and the substrate. When an underlayer is present, either layer or both layers may comprise an imageable composition of the invention, and either or both layers may comprise a photothermal conversion material.

In one embodiment the underlayer comprises the imageable composition of the invention and the upper layer comprises an imageable composition that comprises a QHB-modified phenolic polymer, such as a QHB-modified novolac resin. In a preferred embodiment, the QHB-modified polymer in the underlayer is a QHB-modified acrylic portion joined to a QHB-modified phenolic portion, a QHB-modified polyester portion, or a QHB-modified polyurethane potion. In another preferred embodiment, the QHB-modified polymer in the underlayer is a QHB-modified acrylic portion joined to a QHB-modified phenolic portion.

The underlayer may also comprise an acrylic polymer, such as those described above. Especially useful are the polymers disclosed by Shimazu, U.S. Pat. No. 6,294,311, incorporated herein by reference, which provide resistance both to fountain solution and aggressive washes.

Alternatively, the imageable layer may comprise the imageable composition of the invention and the underlayer may comprise a developer soluble acrylic polymer, such as those disclosed by Shimazu, U.S. Pat. No. 6,352,812, incorporated herein by reference.

### Preparation of the Imageable Elements

The imageable element may be prepared by sequentially applying the underlayer, if present, over the hydrophilic surface of the substrate, and applying the imageable layer over the underlayer if the underlayer is present, or over the hydrophilic surface of the substrate if the underlayer is not present, using conventional coating and/or lamination methods.

The underlayer, if present, may be applied over the hydrophilic surface of the substrate by any conventional method. Typically the ingredients are dispersed or dissolved in a suitable coating solvent, and the resulting mixture coated by conventional methods, such as spin coating, bar coating, gravure coating, or roller coating. The term “coating solvent” includes mixtures of solvents, especially mixtures of organic solvents. Some of materials, such as pigments, may be dispersed rather than dissolved in the coating solvent.

The imageable layer may be applied over the substrate or, if present, the underlayer by any conventional method. Typically the ingredients are dispersed or dissolved in a suitable coating solvent, and the resulting mixture coated by conventional methods, such as spin coating, bar coating, gravure coating, or roller coating. However, when an underlayer is present, care must be taken to avoid mixing of the ingredients of the underlayer and ingredients of the imageable layer during the coating process. This may be accomplished by thoroughly drying the underlayer before coating the imageable layer and coating the imageable layer from a coating solvent in which the underlayer is substantially insoluble.

### Imaging and Processing

Imaging produces an imaged element, which comprises a latent image of imaged (exposed) regions and non-imaged (unexposed) regions in the imageable layer. Development of the imaged element to form a lithographic printing plate converts the latent image to an image by removing the exposed regions, revealing the hydrophilic surface of the underlying substrate.

The positive-working thermally imageable elements may be imaged with a laser or an array of lasers emitting modulated near infrared or infrared radiation in a wavelength region that is absorbed by the element. Infrared radiation, especially infrared radiation in the range of about 800 nm to about 1200 nm, is typically used for imaging thermally imageable elements. Imaging is conveniently carried out with a laser emitting at about 830 nm or at about 1056 nm. Suitable commercially available imaging devices include image setters such as the Creo Trendsetter (CREO, British Columbia, Canada) and the Gerber Crescent 42T (Gerber).

Alternatively, the element may be imaged using a conventional apparatus containing a thermal printing head. An imaging apparatus suitable for use in conjunction with the element includes at least one thermal head but would usually include a thermal head array, such as a TDK Model No. LV5416 used in thermal fax machines and sublimation printers. When exposure is carried out with a thermal head, it is unnecessary that the imageable layer absorb radiation, so it is not necessary that the imageable composition comprise a photothermal conversion material. However, elements that comprise a photothermal conversion material may be imaged with a thermal printing head.

Though not being bound by any theory of explanation, it is believed that thermal imaging breaks the hydrogen bonds of the supramolecular polymer. Following exposure, the exposed regions of the imageable layer can be removed with an aqueous developer prior to reformation of the hydrogen bonds. Thus, developability decreases with time following exposure. The imaged elements should preferably be developed within up to 1 hour, more preferably within up to 30 minutes, most preferably within up to 10 minutes following imaging.

The developer may be any liquid or solution that can penetrate and remove the exposed regions of the imageable layer and the underlying regions of the underlayer, if present, without substantially affecting the complementary unexposed regions. Common components of aqueous developers include surfactants, chelating agents, such as, salts of ethylenediamine tetraacetic acid, organic solvents, such as, benzyl alcohol, and alkaline components, such as, inorganic metasilicates, organic metasilicates, hydroxides and bicarbonates. Useful developers are aqueous solutions having a pH of about 7 or above. Preferred alkaline developers are those that have a pH between about 8 and about 13.5, typically at least about 9, preferably at least about 10. Wholly aqueous developers, i.e., those that do not comprise an added organic solvent, may be used. Although the composition of the developer will depend on the composition of the imageable layer and, if present, the underlayer, the developer typically is an aqueous composition comprising inorganic metasilicates or organic metasilicates. Silicate containing alkaline developers are available, for example, from Kodak Polychrome Graphics LLC.

Development is typically carried out in a processor equipped with an immersion-type-developing bath, a section for rinsing with water, and a drying section. Typically, the developer is applied to the imaged element by rubbing or wiping the element with an applicator containing the developer. Alternatively, the imaged element may be brushed with the developer or the developer may be applied to the precursor by spraying the element with sufficient force to remove the exposed regions. Development may be carried out in a commercially available processor, such as a PK-910 processor (available from Kodak Polychrome Graphics). Following development, the lithographic printing plate is typically rinsed with water and dried. Drying may be conveniently carried out by infrared radiators or with hot air.

An imaged and developed element, typically a lithographic printing plate, is produced. The developed element comprises (1) regions in which the imageable layer and underlying layer, if present, have been removed in the exposed regions revealing the underlying surface of the hydrophilic substrate, and (2) complementary unexposed regions in which the imageable layer and underlying layer, if present, have not been removed.

For printing, the lithographic printing plate is mounted on a lithographic printing press. Printing may be carried out by applying a fountain solution and then lithographic ink to the image on the surface of the plate. The fountain solution is taken up by the imaged (exposed) regions, i.e., the surface of the hydrophilic substrate revealed by imaging and development, and the ink is taken up by the unimaged (unexposed) regions. The ink is then transferred to a suitable receiving material (such as cloth, paper, metal, glass or plastic) either directly or indirectly through the use of an intermediate offset printing blanket to provide an impression of the image.

### INDUSTRIAL APPLICABILITY

The thermally imageable compositions are useful in digital imaging applications, including printing plates and printed circuit boards. The imageable elements are especially useful as lithographic printing plate precursors.

The advantageous properties of this invention can be observed by reference to the following examples, which illustrate but do not limit the invention.

### EXAMPLES

In the Examples, “coating solution” refers to the mixture of solvent or solvents and additives coated, even though some of the additives may be in suspension rather than in solution.

Glossary

| | |
|---|---|
| BASONYL ® Violet | Triarylmethane dye (BASF Corp) |
| D-11 | Blue triarylmethane dye (PCAS Corp) |
| DC-190 | Silicone surfactant (Dow Corning) |
| IH-1225 | Phenol-formaldehyde novolac resin, weight |
| | average molecular weight: 5,550 (Dainippon |
| | Ink & Chemicals) |
| IR-66e | Infrared absorber, λₘₐₓ = 788 nm |
| | (KPG Freundorfer, Munich, Germany) |
| KF654 | IR-dye |
| MC | METHYL CELLOSOLVE ® solvent (2- |
| | methoxyethanol) (Dow) |
| PP-3570G | p-Cresol/phenol-formaldehyde novolac resin, p- |
| | cresol/phenol = 35/65, weight average molecular |
| | weight: 5,852 (Asahi Organic Chemicals) |

### Example 1

This example illustrates preparation of a quadruple hydrogen bonding entity (QHBE)-containing mixture.

Synthesis of 6-Methyl-iso-cytosine

Dry ethanol (600 mL), 91.89 g of guanidine carbonate, and 146.1 g of ethyl acetoacetate were added to a 1 L flask. The reaction solution was gradually heated to reflux temperature and stirred overnight. Ethanol (300 mL) was evaporated, and the reaction mixture was heated under reflux for two hours. After the reaction mixture was cooled, 300 mL of hexane was added. The resulting precipitate was filtered, washed and dried. 119.3 g of 6-methyl-iso cytosine was obtained.

Preparation of a QHBE-Containing Mixture

Into a 500 mL flask fitted with a silica gel drying tube were added 280.48 g of dried N,N-dimethyl acetamide and 43.76 g of dried 6-methyl-iso-cytosine. To this mixture was added 66.22 g of isophorone diisocyanate. The mixture was stirred at ambient temperature for five days. The resulting mixture was used without any further treatment to prepare QHB-modified polymers.

### Example 2

This Example illustrates the preparation of acrylic monomers M-1, M-2, and M-3.

2-(N′-(4-Hydroxyphenyl)ureido)ethylmethacrylate (M-1) N,N-Dimethylacetamide (500 g) and p-aminophenol (173.5 g, 1.6 mol) were added to a 1-L flask. Methacryloyl oxyethyl isocyanate (234.9 g, 1.5 mol) was added dropwise with stirring to the reaction mixture over 1 hour while the reaction mixture was in a cool bath. Then stirring was continued for 5 hours at room temperature. The mixture was monitored for isocyanate functionality using infrared spectroscopy. Concentrated hydrochloric acid (10 mL) was added to the mixture. The resulting mixture stirred for 15 minutes and then poured into 4.5 liter of water. The precipitate was filtered off, washed with water and dried below 40° C. with vacuum. Yield: 370 g of 2-(N′-(4-hydroxyphenyl)ureido)ethylmethacrylate (M-1) [CH₂═C(CH₃)—CO₂—CH₂CH₂—NH—CO—NH-p-C₆H₄—OH].

N-(3-Carboxy-4-hydroxyphenyl)methacrylamide (M-2) N, N-Dimethylacetamide (600 mL), methacrylic acid (95.2 g, 1.1 mol), and ethyl chloroformate (120.1 g, 1.1 mol) were added to a 1-L flask. Triethyl amine (111.8 g, 1.1 mol) was added dropwise with stirring to the reaction mixture over 1 hour while the reaction mixture was in a cool bath. Then stirring was continued for 1 hour at room temperature. Then 5-aminosalicylic acid (141.2 g, 1 mol) was added and the reaction mixture heated at 60° C. for 2 hours and then poured into 5 liter of 1% hydrochloric acid. The precipitate was filtered off, washed with water, and dried below 40° C. with vacuum. Yield: 164.7 g of N-(3-carboxy-4-hydroxyphenyl)methacrylamide (M-2).

N4-Carboxyphenyl methacrylamide (M-3) N,N-Dimethylacetamide (600 mL), methacrylic acid (95.2 g, 1.1 mol), and ethyl chloroformate (120.1 g, 1.1 mol) were added to a 1-L flask. Triethyl amine (111.8 g, 1.1 mol) was added dropwise with stirring to the reaction mixture over 1 hour while the reaction mixture was in a cool bath. Then stirring was continued for 1 hour at room temperature. Then 4-aminobenzoic acid (137.1 g, 1 mol) was added and the reaction mixture heated at 60° C. for 2 hours and then poured into 5 liter of 1% hydrochloric acid. The precipitate was filtered off, washed with water, and dried below 40° C. with vacuum. Yield: 161.0 g of N-(4-carboxyphenyl)methacrylamide (M-3).

### Example 3

This example illustrates the synthesis of a QHB-modified phenol novolac resin (NQ-1).

Into a 500 mL flask fitted with a silica gel drying tube were added 50 g of IH-1225 and 125 g of dried N,N-dimethyl acetamide. To the resulting mixture were added 16.9 g of the QHBE reaction mixture prepared in Example 1 and 0.5 g of dibutyltin dilaurate. The progress of the reaction was monitored by infrared spectroscopy. After 12 hr at 60° C., the reaction mixture was poured into water. The precipitated polymer (NQ-1) was filtered off and dried at 40° C. with vacuum. Yield: 90%

### Example 4

This example illustrates the synthesis of a QHB-modified p-cresol/phenol novolac resin (NQ-2).

The procedure of Example 3 was repeated except that 50 g of PP-3570G and 33.72 of the QHBE reaction mixture prepared in Example 1 and 0.5 g of dibutyltin dilaurate were added. Yield: 92% of dried polymer (NQ-2).

### Example 5

This example illustrates the synthesis of a QHB-modified acrylic resin (AQ-1).

Into a 500 mL flask fitted with a silica gel drying tube and nitrogen gas flow were added 24.1 g of acrylonitrile, 3.6 g of methacrylamide, 20.4 g of M-1 monomer, and 100 g of dried N,N-dimethyl acetamide. A catalytic amount (0.1 g) of 2,2-azobisisobutyronitrile (AIBN) was added and the reaction mixture heated at 100° C. with stirring for 2 hr.

The resulting reaction was cooled to room temperature and 6.1 g of the QHBE reaction mixture prepared in Example 1 and 0.5 g of dibutyltin dilaurate were added. After 12 hr at 60° C., the reaction mixture was poured into water. The precipitated polymer (AQ-1) was filtered off and dried at 40° C. with vacuum. Yield: 89%.

### Example 6

This example illustrates formation of QHB-modified acrylic portion joined to a QHB-modified phenolic portion (MAQ-1).

In a 300 mL flask fitted with a silica gel drying tube were added 120 g of dried N,N-dimethyl acetamide, 4.0 g of the QHB-modified novolac resin formed in Example 3 (NQ-2) and 36.0 g of the QHB-modified acrylic polymer formed in Example 4 (AQ-1). Succinyl chloride (3.0 g) was added very slowly with stirring, followed by 4.3 g of triethyl amine. The reaction mixture was stirred at ambient temperature for 15 hours and poured into water. The precipitated polymer (MAQ-1) was filtered off and dried at 40° C. with vacuum. Yield: 90%.

### Example 7

This example illustrates preparation and evaluation of printing plate precursors in a single layer system. Coating solutions of the following composition were prepared:

| | |
|---|---|
| MC (solvent) | 900 g |
| Polymer, as indicated In Table 1 | 70.0 g |
| NQ-1 | 18.0 g |
| BASONYL ® Violet | 1.7 g |
| IR-66e | 3.0 g |
| Pyromellitic acid | 0.8 g |
| 2-Mercaptobenzimidazole | 3.0 g |
| Triphenylphosphite | 2.7 g |
| DC-190 | 0.8 g |

The coating solutions were coated onto a substrate using a wire wound bar. The substrate was an aluminum sheet that had been electrograined and anodised and post-anodically treated with an aqueous solution of an inorganic phosphate. The resulting imageable elements were dried at 130° C. for 60 seconds. The coating weights of the imageable layer after thorough drying were 1.8±0.1 g/m².

Each element was imaged with 830 nm radiation using a Creo Trendsetter 3230 (CREO Corp., British Columbia, Canada) at 9 W and 150 rpm. The resulting imaged elements were developed in a PK-910 processor at 30° C. for 12 seconds using PD1 positive developer (alkaline developer containing potassium silicate; Kodak Polychrome Graphics, Japan) diluted 1 to 8 with water.

The dried imaged and developed imageable elements were dipped in Daicure roller washer oil containing 10% water for 30 minutes. Daicure roller washer oil is a plate cleaning solution that is used with ultraviolet curable printing inks. Results are given in Table 1.

TABLE I

| Sample | Polymer | Developability | Solvent Resistance^{a} |
|---|---|---|---|
| 1 | NQ-2 | Good | Poor |
| 2 | AQ-1 | Poor | Good |
| 3 | NQ-2/AQ-1 (1/9) | Poor | Good |
| 4 | MAQ-1 | Good | Good |

^{a}Resistance to Daicure Roller Washer Oil containing 10 wt % water

Only the imageable element in which the imageable layer comprised the MAQ-1 polymer showed both good developability and good resistance to UV washer oil.

### Example 8

A printing plate that contained MAQ-1 polymer, produced in the same manner as the printing plate in Example 6, Sample 4, was evaluated on a Man Roland R-700 Printing Press using Daicure Black ink UV ink (Dainippon Ink and Chemicals) and NA-108W fountain solution (Dainippon Ink and Chemicals). The printing plate produced 50,000 good impressions.

### Example 9

This example illustrates the synthesis of a QHB-modified p-cresol/phenol novolac resin (NR-1).

The procedure of Example 4 was repeated except that 100 mL of dried N,N-dimethyl acetamide, 27.7 g of a m/p-novolac resin (m to p ratio=6:4), weight average molecular weight=5,600), 16.2 g of the QHBE reaction mixture prepared in Example 1 and 0.5 g of dibutyltin dilaurate were used. The mixture was tested for isocyanate functionality by titration with N,N-dibutyl amine. Yield: 27.8 g of dried polymer (NR-1).

### Example 10

This example illustrates the synthesis of a QHB-modified phenol novolac resin (NR-2).

The procedure of Example 9 was repeated except that 180 mL of dried N,N-dimethyl acetamide, 50 g of IH-1225, 37.2 g of the QHBE reaction mixture prepared in Example 1 and 0.1 g of dibutyltin dilaurate were used. Yield: 51.0 g of dried polymer (NR-2).

### Example 11

This example illustrates the synthesis of a QHB-modified p-cresol/phenol novolac resin (NR-3).

The procedure of Example 9 was repeated except that 180 mL of dried N,N-dimethyl acetamide, 50 g of PP-3570G, 31.4 g of the QHBE reaction mixture prepared in Example 1 and 0.1 g of dibutyltin dilaurate was used. Yield: 52.0 g of dried polymer (NR-3).

### Example 12

This example illustrates the synthesis of a QHB-modified acrylic resin (AQ-2).

Into a 200 mL flask fitted with a nitrogen gas flow 46.7 g of N,N-dimethylacetamide was heated to 85° C. AIBN (0.15 g) was added and a mixture of 46.7 g of N,N-dimethylacetamide, 13.5 g of M-2, 18.0 g of acrylonitrile, 1.9 g of phenylmaleimide, 3.7 g of methacrylamide and 0.45 g of AIBN added dropwise over 1 hour. Then the reaction mixture was heated at 100° C. and an additional 0.15 g of AIBN was added at intervals of 1 hour until the viscosity was B-C (Gardner density). The mixture was cooled to 60° C. The QHBE solution (4.9 g) prepared in Example 1, 0.5 g of di-n-butyltin dilaurate, and 0.1 g of triethylamine were added and the reaction continued for or 8 hours. The mixture was tested for isocyanate functionality using gel permeation chromatography and then was poured into 1.5 liter of water. The precipitated polymer (AQ-2) was filtered off and dried at 40° C. with vacuum. Yield: 35.1 g of QHB-modified acrylic resin (AQ-2).

### Example 13

This example illustrates the synthesis of a QHB-modified acrylic resin (AQ-3).

Into a 200 mL flask fitted with a nitrogen gas flow 46.7 g of N,N-dimethylacetamide was heated to 85° C. AIBN (0.15 g) was added and a mixture of 46.7 g of N,N-dimethylacetamide, 10.1 g of M-1, 4.4 g of M-3, 17.0 g of acrylonitrile, 1.9 g of phenylmaleimide, 3.7 g of methacrylamide and 0.45 g of AIBN was added dropwise over 1 hour. Then the reaction mixture was heated at 100° C. and an additional 0.15 g of AIBN was added at intervals of 1 hour until the viscosity was B˜C (Gardner density). The mixture was cooled to 60° C. The QHBE solution (4.7 g) prepared in Example 1, 0.5 g of di-n-butyltin dilaurate, and 0.1 g of triethylamine were added and the reaction continued for or 8 hours. The mixture was tested for isocyanate functionality using gel permeation chromatography and then was poured into 1.5 liter of water. The precipitated polymer (AQ-2) was filtered off and dried at 40° C. with vacuum. Yield: 34.3.1 g of QHB-modified acrylic resin (AQ-3).

### Example 14

This example illustrates formation of QHB-modified acrylic portion joined to a QHB-modified phenolic portion (MAQ-2).

The procedure of Example 6 was repeated except that, instead of succinyl chloride, 4.3 g of isopherone diisocyanate was added to the reaction mixture followed by 0.5 g of dibutyl tin dilaurate. After the resulting reaction mixture was stirred for 15 minutes at room temperature, 1.0 g of triethyl amine was added with stirring. After the resulting reaction mixture was stirred for 1 hour at 40° C., it was poured into water. The precipitate was filtered off and dried at 40° C. with vacuum. Yield: 39.3 g of QHB-modified acrylic portion joined to a QHB-modified phenolic portion (MAQ-2).

### Example 15

This example illustrates formation of QHB-modified acrylic portion joined to a QHB-modified phenolic portion (MAQ-3).

The procedure of Example 6 was repeated except that, instead of succinyl chloride, 4.2 g of neopentyl glycol diglycidyl ether was added very slowly with stirring, followed by 0.5 g of N-methyl morpholine. After the resulting reaction mixture was stirred for 12 hour at 40° C., it was poured into water. The precipitate was filtered off and dried at 40° C. with vacuum. Yield: 39.1 g of QHB-modified acrylic portion joined to a QHB-modified phenolic portion (MAQ-3).

### Example 16

This example illustrates formation of QHB-modified acrylic portion joined to a QHB-modified phenolic portion (MAQ-4).

The procedure of Example 6 was repeated except that, instead of AQ-1, 36.0 g of AQ-2 was used. Yield: 38.8 g of QHB-modified acrylic portion joined to a QHB-modified phenolic portion (MAQ-4).

### Example 17

This example illustrates formation of QHB-modified acrylic portion joined to a QHB-modified phenolic portion (MAQ-5).

The procedure of Example 14 was repeated except that 36.0 g of AQ-2 was used. Yield: 39.1 g of QHB-modified acrylic portion joined to a QHB-modified phenolic portion (MAQ-5).

### Example 18

This example illustrates formation of QHB-modified acrylic portion joined to a QHB-modified phenolic portion (MAQ-6).

The procedure of Example 6 was repeated except that, instead of AQ-1, 36.0 g of AQ-3 was used. Yield: 38.7 g of QHB-modified acrylic portion joined to a QHB-modified phenolic portion (MAQ-6).

### Example 19

This example illustrates preparation and evaluation of printing plate precursors in a single layer system. Coating solutions of the following composition were prepared:

| | |
|---|---|
| MC (solvent) | 90% |
| Polymer, as indicated In Table 2 | 7.0% |
| NR-1 | 0.8% |
| NR-2 | 1.0% |
| KF-654 | 0.3% |
| Pyromellitic acid | 0.08% |
| 2-Mercaptobenzimidazole | 0.3% |
| Triphenylphosphite | 0.27% |
| D-11 | 0.17% |
| DC-190 | 0.08% |

The coating solutions were roll coated onto substrate of Example 7. The resulting imageable elements were dried at 130° C. for 60 seconds. The coating weights of the imageable layer after thorough drying were 1.72 g/m².

The resulting imageable elements were exposed and developed as described in Example 7. Developing latitude was evaluated by density difference of the 50% dots developed by developer PD-1 diluted to six parts with water (A) and developer PD-1 diluted to 12 parts with water (B). If density difference was small, the imageable element showed wide developing latitude.

Press life was evaluated by mounting the imaged and developed imageable element (printing plate) on a Man Roland R-700 Printing Press and printing using Daicure Black ink UV ink (Dainippon Ink and Chemicals) and NA-108W fountain solution (Dainippon Ink and Chemicals). Evaluation was based on the total number of printed pages having accurate printing.

Solvent resistance was evaluated by soaking the imaged and developed imageable element (printing plate) in Daicure washer and Daicure roller washer oil (Dainippon Ink & Chemicals) for 30 min, and evaluating the degree of corrosion of the printing plate.

Results are given in Table 2. Developing latitude and solvent resistance are each reported on a scale of 1 to 5, with 5 being best.

TABLE 2

| | | Developing | Press life | Solvent |
|---|---|---|---|---|
| Sample | Polymer | Latitude | (sheet) | Resistance |
| 1 | MAQ-1 | 5 | ≧100,000 | 5 |
| 2 | MAQ-2 | 5 | ≧100,000 | 5 |
| 3 | MAQ-3 | 5 | ≧100,000 | 5 |
| 4 | MAQ-4 | 5 | ≧100,000 | 5 |
| 5 | MAQ-5 | 5 | ≧100,000 | 5 |
| 6 | MAQ-6 | 5 | ≧100,000 | 5 |
| C1 | NR-3 | 5 | 60,000 | 1 |
| C2 | AQ-1 | 3 | 80,000 | 5 |
| C3 | AQ-2 | 3 | 80,000 | 5 |
| C4 | AQ-3 | 3 | 80,000 | 5 |
| C5 | NR-3/AQ-1(1/9) | 4 | 80,000 | 5 |

### Example 20

This example illustrates the synthesis of a QHB-modified acrylic resin (AR-1).

The procedure of Example 12 was repeated, except that a mixture of 46.7 g of N,N-dimethylacetamide, 17.6 g of M-1, 15.8 g of acrylonitrile, 3.7 g of methacrylamide and 0.45 g of AIBN added dropwise over 1 hour. Yield: 32.7 g of QHB-modified acrylic resin (AR-1).

### Example 21

This example illustrates the synthesis of a QHB-modified acrylic resin (AR-2).

The procedure of Example 12 was repeated, except that 46.7 g of N,N-dimethylacetamide, 13.0 g of M-2, 18.5 g of acrylonitrile, 1.9 g on N-phenylmaleimide, 3.7 g of methacrylamide and 0.45 g of AIBN added dropwise over 1 hour. Yield: 34.1 g of QHB-modified acrylic resin (AR-2).

### Example 22

This example illustrates formation of QHB-modified acrylic portion joined to a QHB-modified phenolic portion (ANR-1).

The procedure of Example 6 was repeated except that, instead of NQ-2 and AQ-1, 4.0 g of NR-3 and 36.0 g of AR-1 were used. Yield: 38.7 g of QHB-modified acrylic portion joined to a QHB-modified phenolic portion (ANR-1).

### Example 23

This example illustrates formation of QHB-modified acrylic portion joined to a QHB-modified phenolic portion (ANR-2).

The procedure of Example 14 was repeated except that, instead of NQ-2 and AQ-1, 4.0 g of NR-3 and 36.0 g of AR-1 were used. Yield: 39.9 g of QHB-modified acrylic portion joined to a QHB-modified phenolic portion (ANR-2).

### Example 24

This example illustrates formation of QHB-modified acrylic portion joined to a QHB-modified phenolic portion (ANR-3).

The procedure of Example 6 was repeated except that, instead of NQ-2 and AQ-1, 4.0 g of NR-3 and 36.0 g of AR-2 were used. Yield: 39.8 g of QHB-modified acrylic portion joined to a QHB-modified phenolic portion (ANR-3).

### Example 25

This example illustrates formation of QHB-modified acrylic portion joined to a QHB-modified phenolic portion (ANR-4).

The procedure of Example 15 was repeated except that, instead of NQ-2 and AQ-1, 4.0 g of NR-3 and 36.0 g of AR-1 was used. Yield: 40.0 g of QHB-modified acrylic portion joined to a QHB-modified phenolic portion (ANR-4).

### Example 26

This example illustrates formation of QHB-modified acrylic portion joined to a QHB-modified phenolic portion (ANR-5).

The procedure of Example 14 was repeated except that, instead of NQ-2 and AQ-1, 4.0 g of NR-3 and 36.0 g of AR-2 were used. Yield: 39.6 g of QHB-modified acrylic portion joined to a QHB-modified phenolic portion (ANR-5).

### Example 27

This example illustrates preparation and evaluation of printing plate precursors in a two layer system. Coating solutions of the following composition were prepared for the underlayer:

| | |
|---|---|
| MC (solvent) | 90.6% |
| Polymer, as indicated In Table 3 | 7.05% |
| NR-2 | 1.61% |
| KF-654 | 0.50% |
| D-11 | 0.17% |
| DC-190 | 0.08% |

The coating solutions roll coated onto substrate of Example 7. The resulting elements were dried at 100° C. for 2 minutes. The coating weights of the underlayer were 1.5 g/m².

To form the imageable layer, each underlayer was over coated with a coating solution containing 65.18% 1-methoxy-2-propanol, 27.92% methanol, 6.76% NR-1, 0.10% D-11, and 0.04% DC190. The coating weight of the imageable layer was 0.7 g/m².

The resulting imageable elements were imaged, developed, and evaluated as described in Example 19. Results are shown in Table 3.

TABLE 3

| | Underlayer | Developing | Press life | Solvent |
|---|---|---|---|---|
| Sample | Polymer | Latitude | (sheet) | Resistance |
| 1 | ANR-1 | 5 | ≧100,000 | 5 |
| 2 | ANR-2 | 5 | ≧100,000 | 5 |
| 3 | ANR-3 | 5 | ≧100,000 | 5 |
| 4 | ANR-4 | 5 | ≧100,000 | 5 |
| 5 | ANR-5 | 5 | ≧100,000 | 5 |
| 6 | ANR-6 | 5 | ≧100,000 | 5 |
| C1 | NR-3 | 5 | 60,000 | 1 |
| C2 | AR-1 | 3 | 80,000 | 5 |
| C3 | AR-2 | 3 | 80,000 | 5 |
| C4 | NR-3/AR-1(1/9) | 4 | 80,000 | 5 |

Having described the invention, we now claim the following and their equivalents.

What is claimed is:

1. A QHB-modified polymeric molecule, the QHB-modified polymeric molecule having the structure:
A-L-B;
in which:
A is a QHB-modified phenolic portion, a QHB-modified acrylic portion, a QHB-modified polyester portion, or a QHB-modified polyurethane portion;
B is a QHB-modified phenolic portion, a QHB-modified acrylic portion, a QHB-modified polyester portion, or a QHB-modified polyurethane portion;
L is a joining group; and
A and B are different.

2. The polymeric molecule of claim 1 in which the QHB-modified polymeric molecule comprises at least two 6-methyl isocytosine QHB units.

3. The polymeric molecule of claim 1 in which A is the QHB-modified acrylic portion and B is the QHB-modified phenolic portion, the QHB-modified polyester portion, or the QHB-modified polyurethane portion.

4. The polymeric molecule of claim 3 in which B is the QHB-modified phenolic portion.

5. The polymeric molecule of claim 4 in which the QHB-modified phenolic portion is a QHB-modified novolac resin.

6. The polymeric molecule of claim 5 in which the QHB-modified acrylic portion comprises, in polymerized form, about 20 to 80 wt % of one of more monomers represented by:
CH₂═C(R)—CO₂—X—NH—CO—NH—Y-Z,
in which R is —H or —CH₃; X is a bivalent joining group; Y is a substituted or unsubstituted bivalent aromatic group; and Z is —OH, —COOH, or —SO₂NH₂.

7. The polymeric molecule of claim 6 in which the QHB-modified polymeric molecule comprises at least two 6-methyl isocytosine QHB units.

8. A supramolecular polymer comprising a plurality of QHB-modified polymeric molecules having the structure:
A-L-B;
in which:
A is a QHB-modified phenolic portion, a QHB-modified acrylic portion, a QHB-modified polyester portion, or a QHB-modified polyurethane portion;
B is a QHB-modified phenolic portion, a QHB-modified acrylic portion, a QHB-modified polyester portion, or a QHB-modified polyurethane portion;
L is a joining group; and
A and B are different.

9. The supramolecular polymer of claim 8 in which the supramolecular polymer has an increased rate of solubility in an aqueous developer following thermal exposure.

10. The supramolecular polymer of claim 9 in which the QHB-modified polymeric molecules each comprise at least two 6-methyl isocytosine QHB units.

11. The supramolecular polymer of claim 10 in which A is the QHB-modified acrylic portion and B is the QHB-modified phenolic portion, the QHB-modified polyester portion, or the QHB-modified polyurethane portion.

12. The supramolecular polymer of claim 11 in which B is the QHB-modified phenolic portion.

13. The supramolecular polymer of claim 12 in which the QHB-modified phenolic portion is a QHB-modified novolac resin.

14. The supramolecular polymer of claim 13 in which the QHB-modified acrylic portion comprises, in polymerized form, about 20 to 80 wt % of one of more monomers represented by:
CH₂═C(R)—CO₂—X—NH—CO—NH—Y-Z,
in which R is —H or —CH₃; X is a bivalent joining group; Y is a substituted or unsubstituted bivalent aromatic group; and Z is —OH, —COOH, or —SO₂NH₂.

15. The supramolecular polymer of claim 14 in which the QHB-modified polymeric molecules each comprise at least two 6-methyl isocytosine QHB units.

16. An imageable element, the imageable element comprising a first layer over a support,
in which:
the first layer is a layer of an imageable composition;
the imageable composition comprises a first supramolecular polymer;
the first supramolecular polymer comprises a plurality of QHB-modified polymeric molecules having the structure:
A-L-B;
in which:
A is a QHB-modified phenolic portion, a QHB-modified acrylic portion, a QHB-modified polyester portion, or a QHB-modified polyurethane portion;
B is a QHB-modified phenolic portion, a QHB-modified acrylic portion, a QHB-modified polyester portion, or a QHB-modified polyurethane portion;
L is a joining group;
A and B are different; and
the supramolecular polymer has an increased rate of solubility in an aqueous developer following thermal exposure.

17. The imageable element of claim 16 in which the imageable composition additionally comprises a photothermal conversion material.

18. The imageable element of claim 17 in which the QHB-modified polymeric molecules each comprise at least two 6-methyl isocytosine QHB units.

19. The imageable element of claim 18 in which A is the QHB-modified acrylic portion and B is the QHB-modified phenolic portion, the QHB-modified polyester portion, or the QHB-modified polyurethane portion.

20. The imageable element of claim 19 in which B is the QHB-modified phenolic portion.

21. The imageable element of claim 20 in which the QHB-modified phenolic portion is a QHB-modified novolac resin.

22. The imageable element of claim 21 in which the QHB-modified polymeric molecules each comprise at least two 6-methyl isocytosine QHB units.

23. The imageable element of claim 16 additionally comprising a second layer over the first layer, the second layer comprising a second supramolecular polymer, in which the second supramolecular polymer has an increased rate of solubility in an aqueous developer following thermal exposure.

24. The imageable element of claim 23 in which the imageable composition additionally comprises a photothermal conversion material; in the first supramolecular polymer, A is the QHB-modified acrylic portion, B is the QHB-modified phenolic portion, and the QHB-modified phenolic portion is a QHB-modified novolac resin; and the second supramolecular polymer comprises a QHB-modified novolac resin.

25. The imageable element of claim 16 additionally comprising an underlayer between the first layer and the support.

26. A method for forming an image, the method comprising the steps of:
imaging the imageable element of claim 16, and forming an imaged element comprising exposed and unexposed regions in the imageable layer; and
developing the imaged element with a developer and removing the exposed regions.

27. The method of claim 26 in which imaging is carried out with a thermal printing head.

28. The method of claim 27 in which:
A is the QHB-modified acrylic portion;
B is the QHB-modified phenolic portion; and
the QHB-modified phenolic portion is a QHB-modified novolac resin.

29. The method of claim 26 in which the imageable element additionally comprises a photothermal conversion material and the imaging step is carried out using infrared radiation.

30. The method of claim 29 in which:
A is the QHB-modified acrylic portion;
B is the QHB-modified phenolic portion; and
the QHB-modified phenolic portion is a novolac resin.
